(19) United States
(12) Patent Application Publication
(10) Pub. No.: US 2026/0297794 A1
(43) Pub. Date: Oct. 1, 2026

(54) Method of producing single-crystal spherical metal sodium nanoparticles

(71) Applicant: M. TECHNIQUE CO., LTD., Izumi-shi (JP)

(72) Inventors: Hideki Ohkawa, Izumi-shi (JP); Masakazu Enomura, Izumi-shi (JP)

(21) Appl. No.: 19/477,761

(22) PCT Filed: Apr. 26, 2023
(86) PCT No.: PCT/JP2023/016485

§ 371 Date: Oct. 22, 2025

(51) Int. Cl. C30B 7/14; C09K 11/55; C30B 29/02

(52) U.S. Cl. CPC C30B 7/14; C09K 11/55; C30B 29/02

(57) ABSTRACT

The present invention is related to a method of producing metal sodium nanoparticles which are single crystals and spherical, and have an average particle diameter of 1 nm to 300 nm. The single-crystal spherical metal sodium nanoparticles obtained by the production method of the present invention can generate fluorescence when excited by an ultraviolet light. The single-crystal spherical metal sodium nanoparticles do not have the toxicity of compound semiconductors formed from cadmium, selenium, tellurium, etc., and therefore can be used as a reducing agent for various origin substance. Furthermore, because the single-crystal spherical metal sodium nanoparticles are spherical, they can be used as a negative electrode for a sodium battery.

### TECHNICAL FIELD

The present invention relates to a method of producing single-crystal spherical metal sodium nanoparticles.

### BACKGROUND ART

Metal sodium nanoparticles are nanoparticles made of metal sodium atoms, and those with a particle diameter of less than 10 nm are also called metal sodium quantum dots. Quantum dots that are formed from a metal element such as CdSe, Cd, and Te and exhibit fluorescence are known. However, these quantum dots contain a harmful element and therefore need to be collected after use. Therefore, alternative materials have been sought.

It is known that metal sodium nanoparticles can be produced by a top-down method. As a method of producing metal sodium nanoparticles by the top-down method, for example, a method has been used in which sodium is dispersed in a solvent inactive to metal sodium in a stirring tank by high-speed stirring at a temperature equal to or higher than the melting point of sodium, to prepare sodium fine particles. Patent Literature 1 describes a method of producing a metal sodium dispersion by dispersing metal sodium in a transformer oil.

The method of stirring in a stirring tank has a problem that sodium cannot be produced so as to control the particle diameter of sodium to be a desired one. As a method of improving this problem, Patent Literature 2 describes a method of producing a sodium dispersion in which sodium particles are dispersed in a dispersion medium by stirring metal sodium together with a dispersion medium in a stirring tank, wherein metal sodium particles are produced based on a correlation equation between the average particle diameter of the sodium particles and the tip speed V of the stirring blade. However, Patent Literature 2 does not describe a method of producing metal sodium which are single crystals and spherical, and have a diameter of about nm.

Patent Literature 3 describes a method of producing a dispersion of an alkali metal in a solvent. However, Patent Literature 3 does not describe that sodium particles which is an element of an alkali metal, are single crystals and spherical. The sodium to be dispersed is in a molten state, and a raw material obtained as sodium in advance is used, which is different from the single-crystal spherical metal sodium nanoparticles obtained by reducing a sodium raw material in a solution as in the present invention.

Patent Literature 4 describes a method of using a colloidal suspension for producing gaseous hydrogen, comprising 2 to 60% of alkali metal particles suspended in a neutral hydrophobic diluent, wherein the metal particles are 0.1-1 μm, and the hydrophobic diluent is a substance selected from vegetable oils and mineral oils. However, Patent Literature 4 does not describe that the alkali metal is produced by reduction in a solution, or that the alkali metal is single crystals and spherical.

Patent Literature 5 which was filed by the present applicant, describes a method of producing semiconductor fine particles using a fluid processing apparatus equipped with processing surfaces being capable of approaching to and separating from each other, at least one of which rotates relative to the other. However, no specific examples of metal sodium with extremely high reactivity are described. Single-crystal spherical metal sodium nanoparticles cannot be obtained based on Patent Literature 5.

Patent Literature 6 which was filed by the present applicant, describes a method of producing metal fine particles using a fluid processing apparatus equipped with processing surfaces being capable of approaching to and separating from each other, at least one of which rotates relative to the other. Patent Literature 6 describes that metal sodium can be precipitated. Patent Literature 6 also describes that an ether-based organic solvent can be used for the fluid to be processed, but does not describe at all about the residual water and residual dissolved oxygen concentration contained in the organic solvent. In addition, Patent Literature 6 does not describe the oxidation reduction potential required for the precipitation, or specific examples of the potential order between a substance for reduction to metal sodium particles and metal sodium, or what means can be used to produce them.

Non-Patent Literature 1 describes the calculation results of metal sodium plasmon that depends on the atom number of metal sodium. However, Non-Patent Literature 1 does not describe a specific method of producing metal sodium nanoparticles which calculation results can be confirm.

### PRIOR ART DOCUMENT

### Patent Literature

Patent Literature 1: JP H10-110205
Patent Literature 2: JP 2004-300577
Patent Literature 3: JP 2003-268417
Patent Literature 4: JP 2011-526572
Patent Literature 5: JP 4458202
Patent Literature 6: JP 5950476

### Non-Patent Literature

Non-Patent Literature 1: Physical Chemistry Chemical Physics, Vol. 22, 13285-13291 (2020)

### SUMMARY OF THE INVENTION

### Problem to be Solved by the Invention

The problem of the present invention is to provide a method of producing metal sodium nanoparticles which can emit blue fluorescence when excited by an excitation wavelength of an ultraviolet light, are almost non-toxic, can be densely packed into an electrode material for a secondary battery that does not require recovery, and can be used as a catalyst, a reducing agent, etc.

### Means to Solve the Problem

As a result of intensive research into solving the above problem, the present inventors have discovered that single-crystal spherical metal sodium nanoparticles that are single crystals and spherical, and have an average particle diameter of 1 nm to 300 nm are single crystals that do not have grain boundaries that reduce the luminous efficiency, and therefore can generate high fluorescence when excited by an ultraviolet light, and further can be packed with an electrode material for a secondary battery at high density. Thereby, the present inventors have accomplished the present invention.

Namely, the present invention is as follows.
[1] A method of producing single-crystal spherical metal sodium nanoparticles which are single crystals and spherical, comprising: a step of mixing and reacting a raw material liquid containing sodium halide and a reduction liquid containing an anion of an aromatic compound,
wherein the anion of the aromatic compound is prepared by mixing lithium, sodium or potassium with the aromatic compound.
[2] The method according to [1], wherein an average value of circularities of the single-crystal spherical metal sodium nanoparticles is 0.85 or more,
wherein the circularity is defined by a circularity calculated by the formula: 4πS/Z², using the perimeter (Z) and area (S) of the projected image of the single-crystal spherical metal sodium nanoparticles.
[3] The method according to [1] or [2], wherein the average particle diameter of the single-crystal spherical metal sodium nanoparticles is 1 nm to 300 nm.
[4] The method according to any one of [1] to [3], wherein the sodium halide is sodium iodide, and the molar ratio of lithium, sodium or potassium to sodium iodide is from 2:1 to 1:1.
[5] The method according to any one of [1] to [4], wherein the aromatic compound is at least one selected from the group consisting of 4,4′-di-tert-butylbiphenyl (DBB), biphenyl, naphthalene, and phenanthrene.
[6] The method according to any one of [1] to [5], wherein when the aromatic compound is DBB or biphenyl, the reduction liquid exhibits a lower chemical shift than the neutral aromatic compound in the ¹H-NMR spectrum.
[7] The method according to any one of [1] to [6], wherein when the aromatic compound is DBB or biphenyl, the reduction liquid exhibits a chemical shift value of 2 ppm or more in the ⁷Li-NMR spectrum.
[8] The method according to any one of [1] to [7], wherein the solvent contained in the reduction liquid is tetrahydrofuran, 2-methyltetrahydrofuran, 4-methyltetrahydropyran, 1,2-dimethoxyethane, or a mixture thereof, having a residual water content of 10 ppm or less and a residual oxygen concentration of less than 0.1 ppm.
[9] The method according to any one of [1] to [8], wherein the single-crystal spherical metal sodium nanoparticles are made of cubic crystals.
[10] The method according to any one of [1] to [9], wherein a dispersion obtained by dispersing the single-crystal spherical metal sodium nanoparticles in an organic solvent having an optical refractive index of 1.40 to 1.50 has an absorption peak at 270 nm to 340 nm in the ultraviolet-visible absorption spectrum.
[11] The method according to any one of [1] to [10], wherein the single-crystal spherical metal sodium nanoparticles have a fluorescence maximum in the wavelength range of 380 nm to 450 nm in the fluorescence spectrum.
[12] The method according to any one of [1] to [11], wherein the raw material liquid and the reduction liquid are mixed and reacted using an apparatus,
wherein the apparatus comprises a fluid pressure imparting mechanism for imparting a pressure to the reduction liquid; two processing members of a first processing member and a second processing member, the second processing member being capable of approaching to and separating from the first processing member; and a rotation drive mechanism for rotating the first processing member and the second processing member relative to each other; and
wherein each of the two processing members provides two processing surfaces of a first processing surface and a second processing surface disposed in a position facing with each other; each of the processing surfaces constitute part of a sealed flow path through which the reduction liquid under the pressure is passed;
the apparatus is for mixing and reacting the fluids to be processed, of the raw material liquid and the reduction liquid which contain reactants between both the processing surfaces;
of the first and second processing members, the second processing member is provided with a pressure-receiving surface, and a part of the pressure-receiving surface is comprised of the second processing surface;
the pressure-receiving surface receives pressure applied to the reduction liquid by the fluid pressure imparting mechanism and thereby generates a force to move in the direction of separating the second processing surface from the first processing surface;
the reduction liquid and the raw material liquid being the fluids to be processed under the predetermined pressure are passed between the first and second processing surfaces being capable of approaching to and separating from each other, at least one of which rotates relative to the other, whereby the fluids to be processed form a thin film fluid containing the single-crystal spherical metal sodium nanoparticles;
the apparatus further comprises an introduction path independent of the flow path through which the reduction liquid under the pressure is passed; and one opening leading to the introduction path and being arranged in the second processing surface; and
the raw material liquid is sent from the introduction path and introduced into between the first and second processing surfaces, and the reduction liquid and the raw material liquid are mixed in the thin film fluid.
[13] The method according to [12], wherein the opening for introducing the sodium iodide raw material liquid is located downstream of a point at which the flow of the reduction liquid passing between the two processing surfaces becomes a laminar flow.

### Effects of the Invention

The single-crystal spherical metal sodium nanoparticles produced by the production method of the present invention are single crystals that do not have grain boundaries that reduce the fluorescence efficiency, and therefore can generate fluorescence when excited by an ultraviolet light. Furthermore, the single-crystal spherical metal sodium nanoparticles do not have the toxicity of compound semiconductors formed from cadmium, selenium, tellurium, etc., and therefore can be used without the need to recover them after use. Furthermore, because the single-crystal spherical metal sodium nanoparticles are spherical, they can be densely packed with an electrode material for a secondary ion battery, etc.

### BRIEF DESCRIPTION OF THE DRAWINGS

FIG. 1 shows a ¹H-NMR spectrum of DBB in the single-crystal spherical metal sodium nanoparticle reduction liquid.

FIG. 2 shows a ¹H-NMR spectrum of the DBB anion radical in the single-crystal spherical metal sodium nanoparticle reduction liquid.

FIG. 3 shows a ¹H-NMR spectrum of the tert-butyl group of DBB in the single-crystal spherical metal sodium nanoparticle reduction liquid.

FIG. 4 shows a ¹³C-NMR spectrum of THF in the single-crystal spherical metal sodium nanoparticle reduction liquid.

FIG. 5 shows a ⁷Li-NMR spectrum of lithium cation when THF was used as the solvent for the single-crystal spherical metal sodium nanoparticle reduction liquid.

FIG. 6 shows the time-dependent change of a half width of lithium cation in ⁷Li-NMR spectrum when THF was used as the solvent for the single-crystal spherical metal sodium nanoparticle reduction liquid, and after the solution was prepared.

FIG. 7 shows a ⁷Li-NMR spectrum of lithium cation when 4-methyltetrahydropyran (4MeTHP) was used as the solvent for the single-crystal spherical metal sodium nanoparticle reduction liquid.

FIG. 8 shows a ²³Na-NMR spectrum of sodium iodide THF solution of the single-crystal spherical metal sodium nanoparticle raw material liquid.

FIG. 9 shows a TEM observation image of the single-crystal spherical metal sodium nanoparticles produced in Example 1-1.

FIG. 10 shows a high-magnification TEM observation image of the single-crystal spherical metal sodium nanoparticles produced in Example 1-1.

FIG. 11(a) shows an XRD pattern of the single-crystal spherical metal sodium nanoparticles produced in Example 1-2, and collected by low acceleration centrifugation. FIG. 11(b) shows an XRD pattern of the single-crystal spherical metal sodium nanoparticles produced in Example 1-2, and collected by high acceleration centrifugation.

FIG. 12 shows a ultraviolet-visible absorption spectrum of the dispersion of the single-crystal spherical metal sodium nanoparticles produced in Example 1-3 in hexane or tetrahydrofuran (THF) as the dispersion solvent.

FIG. 13 shows a fluorescence spectrum of the dispersion of the single-crystal spherical metal sodium nanoparticles produced in Example 1-4 in benzene.

FIG. 14 shows a fluorescence spectrum of the dispersion of the single-crystal spherical metal sodium nanoparticles produced in Example 1-4 in THF.

### EMBODIMENT FOR CARRYING OUT THE INVENTION

Hereinafter, embodiments of the present invention will be described. However, the present invention is not limited to only the embodiments described below. Further, an exemplary application thereof to a light emitting material that emits fluorescence will be described, but the applications of the single-crystal spherical metal sodium nanoparticles produced by the production method of the present invention are not limited thereto.

### 1. Single-Crystal Spherical Metal Sodium Nanoparticles

The single-crystal spherical metal sodium nanoparticles produced by the production method of the present invention are single crystals and spherical, and have an average particle diameter of 1 nm to 300 nm. In case of the average particle diameter of 300 nm or more, when using the single-crystal spherical metal sodium nanoparticles as a negative electrode material for a secondary battery, it is difficult to achieve packing at high density. The average value of circularity of the single-crystal spherical metal sodium nanoparticles is preferably 0.85 or more, more preferably 0.90 or more, still more preferably 0.92 or more. The average value of circularity is calculated using the formula: 4πS/Z² using the perimeter (Z) and area (S) of a projected image of the single-crystal spherical metal sodium nanoparticle observed by a transmission electron microscope. When attempting to utilize fluorescence from the single-crystal spherical metal sodium nanoparticles, the average particle diameter of the single-crystal spherical metal sodium nanoparticles is preferably 1.2 nm to 20 nm, more preferably 1.5 nm to 15 nm, more preferably 2 nm to 10 nm.

The single-crystal spherical metal sodium nanoparticles preferably have an absorption maximum at less than 400 nm in the ultraviolet-visible absorption spectrum.

The single-crystal spherical metal sodium nanoparticles are preferably single-crystal spherical metal sodium nanoparticles that exhibit a fluorescence maximum in the wavelength range of 400 nm to 600 nm in the fluorescence spectrum.

Fluorescence of metal sodium nanoparticles occurs by the following mechanisms.
(A) Control of fluorescence color by controlling a physical factor of changing the band gap of electron energy according to the particle diameter of metal sodium nanoparticles (known as quantum effect).
(B) Involvement of the surface state of the metal sodium nanoparticles to fluorescence due to the presence of a slightly oxidized surface layer on the surface of the metal sodium nanoparticles.

The single-crystal spherical metal sodium nanoparticles of the present invention preferably generate a fluorescence maximum in the wavelength range of 400 nm to 600 nm.

### 2. Method of Producing Single-Crystal Spherical Metal Sodium Nanoparticles

The production method of the present invention is a method of producing single-crystal spherical metal sodium nanoparticles that are single crystals and spherical, and have an average particle diameter of 1 nm to 300 nm, comprising: a step of mixing and reacting a raw material liquid containing sodium halide and a reduction liquid containing an anion of an aromatic compound, wherein the anion of the aromatic compound is prepared by mixing lithium, sodium or potassium with the aromatic compound. For example, the single-crystal spherical metal sodium nanoparticles can be produced by mixing the liquid (Liquid B) containing a raw material of single-crystal spherical metal sodium nanoparticles and the reduction liquid (Liquid A) containing metal lithium and an aromatic compound in a thin film fluid formed between two processing surfaces that are arranged opposite to each other and can approach to and separate from each other, at least one of which rotates relative to the other.

### (Single-Crystal Spherical Metal Sodium Nanoparticle Raw Material Liquid (Liquid B))

The raw material of the single-crystal spherical metal sodium nanoparticles is not particularly limited as long as it is a substance that can precipitate single-crystal spherical metal sodium nanoparticles by reduction. Preferably, the raw material includes sodium halide, and more preferably sodium iodide, etc.

The solvent for the single-crystal spherical metal sodium nanoparticle raw material liquid is not particularly limited as long as it is a substance that can reduce the raw material of the single-crystal spherical metal sodium nanoparticles to precipitate the single-crystal spherical metal sodium nanoparticles, and is inactive and does not affect the reduction reaction. Preferably, the solvent includes ether, etc., more preferably tetrahydrofuran (THF), 1,2-dimethoxyethane (DME), 2-methyltetrahydrofuran, 4-methyltetrahydropyran, or a mixture thereof. These solvents have a higher boiling point than diethyl ether, so that temperature stability may be ensured, and they have low reactivity with alkali metals, so that by-products due to decomposition of the solvent may be suppressed.

### (Residual Water/Residual Oxygen in Solvent)

It is necessary in the present invention to use a solvent in which the residual water is 10 ppm or less and the residual oxygen is less than 0.1 ppm. The reason is that when the single-crystal spherical metal sodium nanoparticles are produced in a solvent by a reduction reaction, if the residual water exceeds 10 ppm, there will be an inconvenience that the metal sodium particles will be completely oxidized down to their innermost parts.

### (Single-Crystal Spherical Metal Sodium Nanoparticle Reduction Liquid (Liquid A))

The reducing agent contained in the single-crystal spherical metal sodium nanoparticle reduction liquid is not particularly limited as long as it can reduce the raw material of the single-crystal spherical metal sodium nanoparticles contained in the single-crystal spherical metal sodium nanoparticle reduction liquid to precipitate the single-crystal spherical metal sodium nanoparticles. Examples of the reducing agent include a combination of metal lithium with an aromatic compound.

It has been reported that the oxidation reduction potential of metal sodium in THF solvent which is an example of the production method of the present invention, is −3.04 V (based on the ferrocene/ferricinium ion (Fc/Fc⁺) potential standard). When converted it to an Ag/AgCl electrode standard, this corresponds to −2.84 V.

The aromatic compound includes those that can receiver one electron from metal lithium to produce a lithium cation and an aromatic compound anion (radical anion). The aromatic compound anion with one electron transferred has one electron in the lowest unoccupied molecular orbital (LUMO) of the aromatic compound. For the reduction to produce single-crystal spherical metal sodium nanoparticles, the potential of the aromatic compound anion needs to be lower than −2.84 V. A preferred aromatic compound includes 4,4′-di-tert-butylbiphenyl (DBB) (−3.13 V).

In the production method of the present invention using an aromatic compound as a reducing agent, it is possible to utilize a disproportionation reaction by electron transfer between two molecules of aromatic compound anion radicals. This disproportionation reaction between two molecules is a reaction which forms a naphthalene dianion and a neutral naphthalene wherein the naphthalene dianion is a divalent anion formed by further one electron transfer to a naphthalene anion radical. Since the oxidation reduction potential of the naphthalene dianion is lower than that of the naphthalene anion radical (−2.53 V), it is possible to produce metal sodium nanoparticles even if naphthalene is used. In addition to naphthalene, aromatic compounds that generate dianions having a lower potential than the anion radical by the disproportionation reaction, include biphenyl anion radical (−2.68 V), biphenyl dianion (−3.18 V), phenanthrene anion radical (−2.49 V), phenanthrene dianion (−3.13 V), and a mixture thereof, etc., preferably DBB, biphenyl, etc. It is because it was possible to produce metal sodium nanoparticles using these aromatic compounds.

The molar ratio of metal lithium and the aromatic compound is, for example, 1:1 to 1:5, preferably 1:1 to 1:1.2, and more preferably 1:1 to 1:1.15. The molar ratio of metal lithium to the raw material of the single-crystal spherical metal sodium nanoparticles is, for example, 10:1 to 1.2:1, preferably 7:1 to 1.5:1, and more preferably 5:1 to 3:1. It is preferable to use metal lithium in excess of the raw material of the single-crystal spherical metal sodium nanoparticles. By using an excessive amount of metal lithium, the single-crystal spherical metal sodium nanoparticles can be produced. When using metal lithium in an amount of ¾ of the amount of the raw material of the single-crystal spherical metal sodium nanoparticles, the raw material would not be completely reduced, so that halogen atoms derived from the raw material remain in the single-crystal spherical metal sodium nanoparticles, and the resulting metal sodium nanoparticles become polycrystalline and no longer spherical. Examples of the solvent for the single-crystal spherical metal sodium nanoparticle reduction liquid include the above solvent used in the single-crystal spherical metal sodium nanoparticle raw material liquid. The concentration of metal lithium in the single-crystal spherical metal sodium nanoparticle reduction liquid is not particularly limited, but is determined according to the molar ratio of metal lithium and the raw material of the single-crystal spherical metal sodium nanoparticles described above.

### (Low Temperature Preparation of Reduction Liquid)

The alkali metal can be dissolved in an ether-based organic solvent in the presence of an aromatic compound. However, when the dissolution temperature is 30° C. or higher, the aromatic compound anion become unstable, and a chemical reaction occurs between the aromatic compound and the alkali metal atom, which reduces the ability of the reduction liquid. For example, when naphthalene (molecular formula: C₁₀H₈) is used as the aromatic compound and lithium (Li) is used as the alkali metal, it has become a problem that the concentration of the naphthalene anion acting as a reducing agent tends to be changed due to generation of a compound such as C₁₀H₇Li. This has also become a problem when DBB is used as the aromatic compound. For this reason, in the production method of the present invention, the liquid preparation temperature at the stage of preparing the single-crystal spherical metal sodium nanoparticle reduction liquid is maintained below 30° C., allowing the aromatic compound anion to exist stably and suppressing the decomposition of the aromatic compound anion.

### (Solvent Molecule Intervened Between Alkali Metal Cation and Aromatic Compound Anion)

The aromatic compound anion generated by the electron transfer of metal lithium to an aromatic compound can bond with the metal lithium cation generated by the electron transfer via Coulomb force. The state in which the lithium cation and the aromatic compound anion are bonded via Coulomb force can be evaluated from the chemical shift value and spectral line width of the ⁷Li-NMR spectrum. The state in which the lithium cation and the aromatic compound anion are bonded via Coulomb force can be confirmed by the fact that the spectral line width is wider than that in the state in which only lithium cation is dissolved in the solvent. The usable time of the reduction liquid can be estimated from this spectral line width, so that the state in which the reduction power of the reduction liquid is maintained can be confirmed by ⁷Li-NMR spectrum measurement before the reduction for the single-crystal spherical metal sodium nanoparticles. In this way, by confirming before the production that the reduction power is maintained in the same level as that when prepared, the spread of the particle diameter distribution of the resulting single-crystal spherical metal sodium nanoparticles can be reduced. As described above, when metal lithium and DBB are dissolved in THF, it is possible to confirm whether the reduction power of the reduction liquid is suitable for producing the single-crystal spherical metal sodium nanoparticles by measuring in the ⁷Li-NMR spectrum a DBB anion radical state of the aromatic compound DBB changed from a neutral state, and the chemical shift and the spectral line width reflecting the bonding with the lithium cation due to Coulomb force.

### (Inhibition of Polymerization of THF Solvent)

The necessity of preparation of the reduction liquid at a low temperature is as described above from the viewpoint of solvation. In addition to this, it is preferable to keep the storage temperature after preparation low. When the storage temperature of the reduction liquid is high, if a cyclic ether such as THF is used as the solvent, a reduction polymerization reaction of the cyclic ether occurs due to the aromatic compound anion. When a polymer is produced by such polymerization of the cyclic ether, it will be mixed with the single-crystal spherical metal sodium nanoparticles, so it is preferable to inhibit the polymerization reaction. Examples of polymerization reaction inhibitors for the cyclic ether such as THF include phenol-based polymerization inhibitors which are added to inhibit generation of a peroxide of the cyclic ether such as THF, and preferably BHT (2,6-di-tert-butyl-4-methylphenol).

### (Method of Producing Single-Crystal Spherical Metal Sodium Nanoparticles: Apparatus)

The single-crystal spherical metal sodium nanoparticles of the present invention can be produced, for example, by mixing a raw material liquid (Liquid B) containing the raw material for single-crystal spherical metal sodium nanoparticles and a reduction liquid (Liquid A) containing metal lithium and an aromatic compound in a thin film fluid formed between two processing surfaces that are arranged opposite to each other and can approach to and separate from each other, at least one of which rotates relative to the other.

Examples of the apparatus used in the production method of the present invention include a fluid processing apparatus as proposed by the present applicant and described in JP 2009-112892. The apparatus comprises a stirring tank having an inner peripheral surface which cross-section is circular, and a mixing tool attached to the stirring tank with a slight gap to the inner peripheral surface of the stirring tank, wherein the stirring tank comprises at least two fluid inlets and at least one fluid outlet; from one of the fluid inlets, the first fluid to be processed containing one of the reactants among the fluids to be processed is introduced into the stirring tank; from one fluid inlet other than the above inlet, the second fluid to be processed containing one of reactants different from the above reactant is introduced into the stirring tank through a different flow path. At least one of the stirring tank and the mixing tool rotates at a high speed relative to the other to let the above fluids be in a state of a thin film; and in the above thin film, the reactants contained in at least the first and second fluids to be processed are reacted.

Preferably, the raw material liquid (Liquid B) and the reduction liquid (Liquid A) are mixed in the thin film fluid to produce the single-crystal spherical metal sodium nanoparticles. The single-crystal spherical metal sodium nanoparticles are produced in the following steps: at first, clusters which are aggregates of metal sodium atoms, are generated as nuclei of the single-crystal spherical metal sodium nanoparticles, and then these clusters further aggregate to grow the single-crystal spherical metal sodium nanoparticles. Even if Liquid B comes into contact with Liquid A at a temperature of less than 10° C. and the reaction starts, the frequency of generation of nuclei for growth of the single-crystal spherical metal sodium nanoparticle is low, so that the frequency of contact between clusters on the nuclei of the single-crystal spherical metal sodium nanoparticles is also low. Therefore, the growth of the single-crystal spherical metal sodium nanoparticles is less susceptible to the influence of the change in the raw material liquid concentration due to the growth of surrounding single-crystal spherical metal sodium nanoparticles, and the supply of the raw material necessary for the growth of the single-crystal spherical metal sodium nanoparticles is uniform.

The temperature of the single-crystal spherical metal sodium nanoparticle reduction liquid (Liquid A) to be introduced into the thin film fluid formed between two processing surfaces being capable of approaching to and separating from each other, at least one of which rotates relative to the other, may be, for example, −30° C. to 25° C., preferably −10° C. to 25° C., and more preferably 0° C. to 25° C.

The temperature of the single-crystal spherical metal sodium nanoparticle raw material liquid (Liquid B) to be introduced into the thin film fluid formed between two processing surfaces being capable of approaching to and separating from each other, at least one of which rotates relative to the other, may be, for example, −10° C. to 25° C., preferably 0° C. to 25° C., and more preferably 10° C. to 25° C. In Examples 1 to 3, production was performed at 23° C. of the temperature of Liquid B, and as a result, the single-crystal spherical metal sodium nanoparticles that were single crystals and spherical, and could generate fluorescent, could be produced.

In the production of the single-crystal spherical metal sodium nanoparticles, for example, lithium chloride is produced as a by-product. Lithium chloride has high solubility in the reaction solvent, so it can be easily separated from the single-crystal spherical metal sodium nanoparticles by centrifugation.

### 3. Application of Single-Crystal Spherical Metal Sodium Nanoparticles

The single-crystal spherical metal sodium nanoparticles of the present invention can be used, for example, in a luminescent material that produce fluorescence, a negative electrode of a lithium ion battery, a reducing agent for various organic substances, a catalyst, etc.

### EXAMPLE

Hereinafter, the present invention is explained in more detail with reference to Examples, but the present invention is not limited only to these Examples.

### (Transmission Electron Microscopy (TEM): Preparation of Sample for TEM Observation)

The single-crystal spherical metal sodium nanoparticles obtained in the Examples and Comparative Examples were dispersed in THF at a concentration of approximately 0.001% in a container. The container containing the resulting dispersion was introduced into a glove box under an argon atmosphere, and the dispersion was dropped onto a carbon support film and dried to prepare a sample for TEM observation.

### (TEM Observation)

A transmission electron microscope JEM-2100 (JEOL Ltd.) was used for TEM observation of the single-crystal spherical metal sodium nanoparticles. The above sample for TEM observation was used as a sample. The observation condition was an accelerating voltage of 200 kV and an observation magnification of 10,000 times or more. The particle diameter was calculated from the distance between the maximum outer circumferences of the single-crystal spherical metal sodium nanoparticles observed by TEM, and the average value (average particle diameter) of the results of measuring the diameters of the 50 single-crystal spherical metal sodium nanoparticles was calculated.

### (Confirmation of Generation of Aromatic Compound Anion by NMR Spectroscopy)

The case using naphthalene as an example of an aromatic compound, is explained. Metal lithium was added to a THF solution of naphthalene to generate naphthalene anion as a reduced species. Its generation was confirmed by ¹H-NMR and ⁷Li-NMR spectra. The measurement sample was prepared by filling an NMR sample tube with the reduction liquid in a glove box under an argon atmosphere, was mixed with tetramethylsilane (TMS) as a chemical shift standard substance, was sealed, and then was removed from the glove box under an argon atmosphere. This sample was measured by the transmission method using a Fourier transform nuclear magnetic resonance spectrometer (JEOL Ltd.). The measurement condition was 23° C. to 25° C., with 128 accumulations for ¹H-NMR and 16 accumulations for ⁷Li-NMR.

### (Fluorescence Spectrum)

The fluorescence spectrum of the single-crystal spherical metal sodium nanoparticles was measured using the spectrofluorometer FT-6500 (JASCO Corporation). The above sample for TEM observation was used as a sample. The sample liquid dispersed in THF was used as a sample. The sample was placed in a quartz cell (optical path length: 1 cm) in a glove box under an argon atmosphere, the upper part was sealed, and then it was removed from the glove box and measured. The measurement condition was: the excitation bandwidth of 3 nm, fluorescence bandwidth of 3 nm, response of 0.1 seconds, scan rate of 100 nm/min, and data acquisition interval of 0.5 nm.

### (Ultraviolet-Visible: UV-Vis Absorption Spectrum Measurement)

The UV-vis (ultraviolet-visible) absorption spectrum of the single-crystal spherical metal sodium nanoparticles was measured using an ultraviolet-visible-near infrared spectrophotometer (product name: V-770, JASCO Corporation). The measurement condition was: the measurement range of 200 nm to 900 nm, a sampling rate of 0.2 nm and a slow measurement speed. A 10 mm thick quartz cell for liquid was used for the measurement.

### (Circularity)

Circularity was calculated as an index for evaluating the sphericity of the single-crystal spherical metal sodium nanoparticles as follows. For the circularity of the single-crystal spherical metal sodium nanoparticles, the image obtained by TEM observation was approximated to an ellipse by using the image software ITEM for TEM (Olympus Soft Imaging Solutions, GmbH). Next, the major axis (D), perimeter (Z) and area (S) of the ellipse obtained from the projected image of the single-crystal spherical metal sodium nanoparticles, were determined from the analysis results of the TEM image analysis software. By using the values of the perimeter (Z) and the area (S), 4πS/Z² was calculated to obtain the circularity. As the circularity value is closer to 1, the particle is closer to a spherical shape. When the shape of the particle is truly spherical, the circularity is maximum 1.

In addition, an average value of the major axis (D) of the ellipse was determined and defined as the average particle diameter. The measurements were calculated for 50 independent single-crystal spherical metal sodium nanoparticles.

### (X-Ray Diffraction: XRD)

For X-ray diffraction (XRD) measurement, a powder X-ray diffraction measurement device EMPYREAN (Spectris Corporation, Malvern Panalytical Division) was used. The measurement condition was: measurement range: 10 to 100 [2θ], Cu anticathode, tube voltage of 45 KV, tube current of 40 mA, and scanning speed of 0.013°/min.

### Example 1

In Example 1, a THF solution of sodium iodide as a raw material (single-crystal spherical metal sodium nanoparticle raw material liquid) was reduced with a DBB dissolved THE solution of metal lithium (single-crystal spherical metal sodium nanoparticle reduction liquid) to produce the single-crystal spherical metal sodium nanoparticles. Table 1 shows the formulations of Examples 1-1 to 1-4. Table 1 shows a case where the molar ratio of metal lithium to sodium iodide is 1:1, but in the present invention, a molar ratio of metal lithium to sodium iodide of up to 2:1 is applicable. In addition to metal lithium, metal sodium and metal potassium can also be used in a similar molar ratio.

TABLE 1

| | | | | | Second fluid | |
|---|---|---|---|---|---|---|
| | | | | | (Liquid B) | |
| | | | | | (Single-crystal | |
| | First fluid (Liquid A) | | | | spherical metal | |
| | (Single-crystal spherical metal sodium | | | | sodium nanoparticle | |
| | nanoparticle reduction liquid) | | | | raw material liquid) | |
| | Raw | | Raw | | Raw | |
| | material | [mol/L] | material | [mol/L] | material | [mol/L] |
| Example 1-1 to | Li | 0.1 | DBB | 0.1 | NaI | 0.1 |
| Example 1-4 | | | | | | |

The solvent used in Example 1 was ultra-dehydrated tetrahydrofuran (Fujifilm Wako Pure Chemical Industries, Ltd.) with a residual water content of 10 ppm or less. In a glove box under an argon atmosphere, a single-crystal spherical metal sodium nanoparticle reduction liquid (Liquid A) and a single-crystal spherical metal sodium nanoparticle raw material solution (Liquid B) were prepared. Specifically, the single-crystal spherical metal sodium nanoparticle reduction liquid of Liquid A was prepared by dissolving metal lithium so as to be at a concentration of 0.1 mol/L in a THF solution in which DBB was dissolved so as to be at a concentration of 0.1 mol/L at a preparation temperature of 20° C. using a glass-coated magnetic stirrer. Similarly, sodium iodide which was the single-crystal spherical metal sodium nanoparticle raw material in Liquid B, was dissolved in THF, and then was stirred with a glass-coated magnetic stirrer for at least 60 minutes. Regarding the substances represented by the chemical formulas or abbreviations in Table 1, DBB is 4,4′-di-tert-butylbiphenyl (Tokyo Chemical Industry Co., Ltd.), NaI is sodium iodide (Kanto Chemical Co., Ltd.), and Li is metal lithium (Kishida Chemical Co., Ltd.).

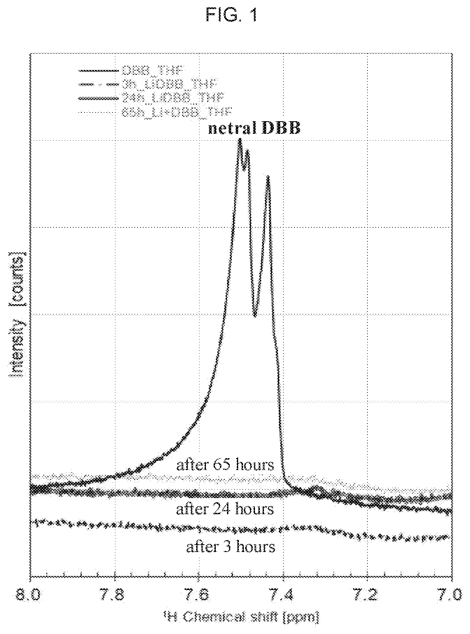

Generation of 4,4′-di-tert-butylbiphenyl (DBB) anion in Liquid A was confirmed by the ¹H-NMR spectrum shown in FIG. 1. The neutral DBB molecule before electron transfer showed a chemical shift of 7.4 ppm to 7.6 ppm, but the peak disappears due to generation of the DBB anion radical.

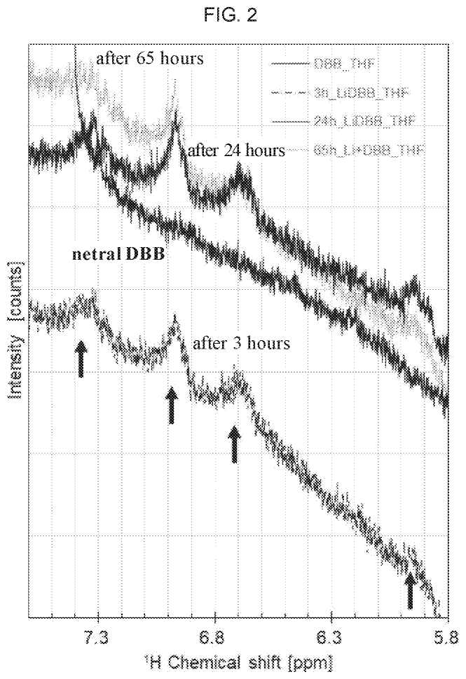

Since change of the reduction power of Liquid A will affect the particle diameter distribution of the produced single-crystal spherical metal sodium particles, it is necessary to confirm the reduction power. FIG. 2 shows the ¹H-NMR spectrum regarding generation of DBB anion radical that had accepted an electron produced by dissolution of metal lithium. The four peaks observed at 5.8 ppm to 7.4 ppm were due to generation of the DBB anion radical, and their peak width increased as the DBB anion radical solvated with a lithium cation and a THF molecule.

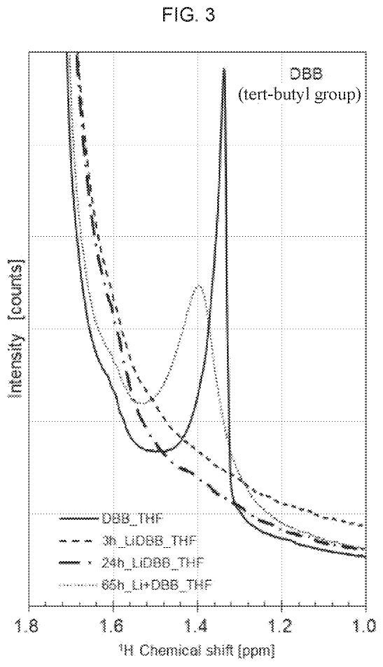

FIG. 3 shows the ¹H-NMR spectrum of the tert-butyl group which is a substituent of DBB. It was confirmed that the peak at 1.34 ppm disappeared due to generation of the DBB anion radical, but after 65 hours, the peak at 1.4 ppm reappeared. This reappearance is due to decrease of the Coulomb force between the DBB anion radical and the lithium cation, and it is considered that the reduction power is maintained for up to 24 hours.

The DBB anion radical can form an ion pair bound with a lithium cation via Coulomb force. When an aromatic compound anion and a metal cation form an ion pair, three states are known. (1) An ion pair in which the DBB anion radical and a lithium cation are directly bound by Coulomb force without intervention of a solvent [DBB′⁻Li⁺], (2) An ion pair in which a solvent is intervened between the DBB anion radical and a lithium cation [DBB′⁻/THF/Li⁺], and (3) An ion pair in which the DBB anion radical and a lithium cation are respectively solvated and bound by Coulomb force [THF/DBB′⁻/THF/THF/Li⁺/THF] are possible. The Coulomb force between the ion pair is the strongest in (1), and the ion pairs in (2) and further (3) are in a bonding state by weaker Coulomb force. Since the state of these ion pairs is reflected in the NMR spectrum, it is possible to evaluate the reduction power by also measuring the NMR of the solvent that may be intervened between the DBB anion radical and the lithium cation.

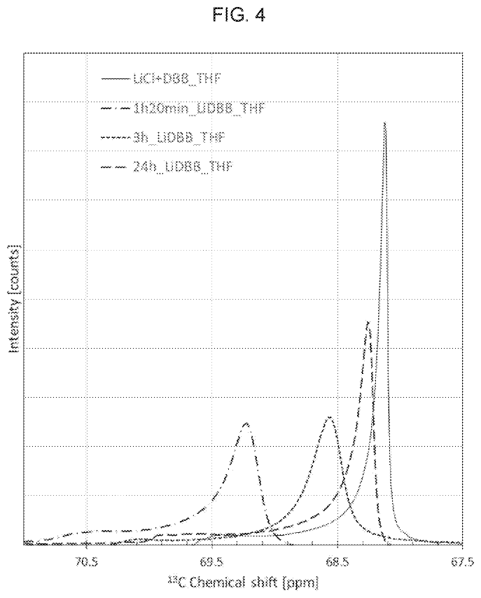

FIG. 4 shows the spectrum of the carbon atom of the CH₂ at the positions 2 and 5 which are bonded to oxygen in the THF in the reduction liquid measured by ¹³C-NMR. Since these carbon atoms are bonded to oxygen, it is sensitive to the solvation state by the oxygen atom of THF, the solvation state of THF with a lithium cation or the DBB anion radical can be confirmed by the chemical shift shown by these carbon atoms. As time passes after metal lithium was added, the peak of THF shifted lower. After 65 hours, the chemical shift and spectral line width of the peak coincided with the same chemical shift and spectral line width as the DBB dissolved THF solution that does not contain a lithium cation. This result is considered to indicate that the solvation state of neutral DBB molecule with no lithium cation by THF and the solvation state of the DBB anion radical with a lithium cation by THF are in a similar state, so it is determined that the reduction liquid has almost no reduction power after 65 hours. This result corresponds to the behavior shown in FIG. 3, in which the peak of the tert-butyl group of the DBB anion radical in ¹H-NMR reappeared after 65 hours.

Since the electron generated by the dissolution of metal lithium is transferred to the DBB and metal lithium becomes a lithium cation, this cation generation can be confirmed by change of the chemical shift and the spectral line width at around 3.8 ppm in the ⁷Li-NMR spectrum. Even 24 hours after the addition of metal lithium, the spectral line width was broadened, which reflected the state in which a lithium cation and the DBB anion directly interacted with each other via Coulomb force.

The interaction between a lithium cation and the DBB anion radical broadens the spectral line width in the above cases (1) and (2). This indicates that the two states, direct interaction via Coulomb force and interaction through the solvent, contribute to the broadening of the spectral line width, and therefore the reduction power of the reduction liquid is maintained.

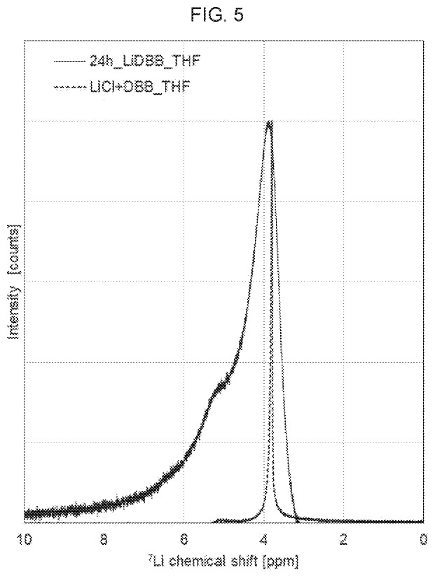

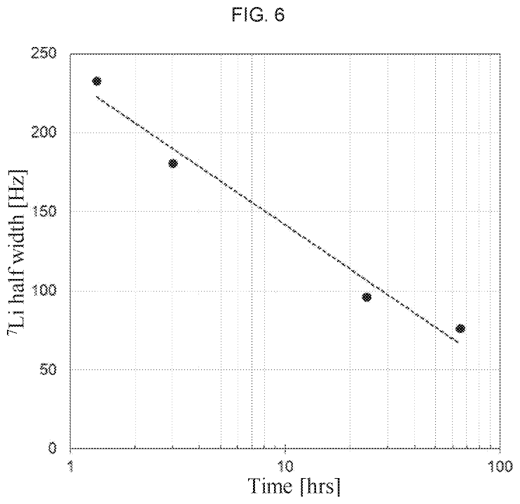

FIG. 5 shows the spectrum of lithium cation of the ⁷Li-NMR spectrum of the DBB⁻ THF solution in which metal lithium was dissolved at the concentration of 0.1 mol/L when THF was used as the solvent in the reduction liquid. FIG. 6 shows the time-dependent change in the line width of this NMR spectrum. After 65 hours of preparation, the spectral line width was close to that of the DBB THF solution with no lithium cation, and therefore it can be determined that the reduction power of the reduction liquid has decreased. As described above, the reduction power of the reduction liquid for producing the single-crystal spherical metal sodium nanoparticles can be evaluated from the ¹H-NMR spectrum, ¹³C-NMR spectrum, and ⁷Li-NMR spectrum, and it is necessary to use the reduction liquid within 24 hours after addition of metal lithium. The state of an ion pair in which a lithium cation and a DBB anion radical are directly bound by Coulomb force, and the state of an ion pair in which a lithium cation and a DBB anion radical are bound by Coulomb force with intervention of a THF molecule, are thought to be reflected in the two peaks on the high chemical shift side obtained by spectral waveform separation of the spectrum after 24 hours. The chemical shifts and the spectral line widths (shown in parentheses) of the two peaks obtained by waveform separation of the spectrum after 24 hours were 3.823 ppm (96.8 Hz) and 4.528 ppm (406.8 Hz).

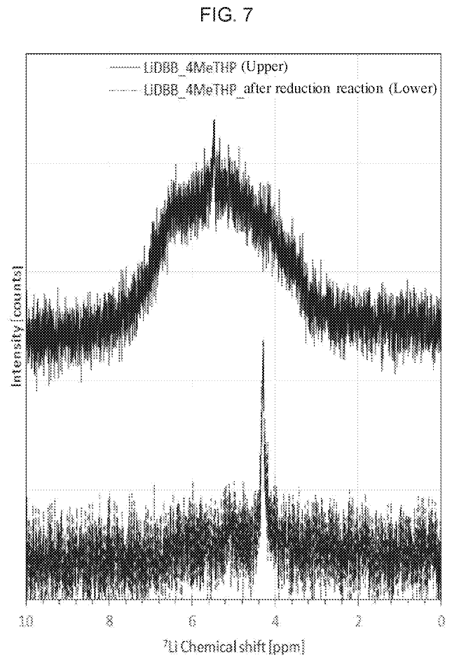

FIG. 7 shows the spectrum of lithium cation in the ⁷Li-NMR spectrum when 4-methyltetrahydropyran (4MeTHP) was used as the solvent for the reduction liquid. As in the case of using THE as the solvent for the reduction liquid, the spectrum width after preparation was broadened, and it was confirmed that an ion pair of a lithium cation and a DBB anion radical was formed in the presence of 4MeTHP. In addition, in the spectrum after centrifugation of the reaction liquid after the reduction reaction with a THF solution of sodium iodide, the spectrum width was narrowed, indicating that the DBB anion radical had changed into a neutral DBB molecule and had an interaction with the lithium cation.

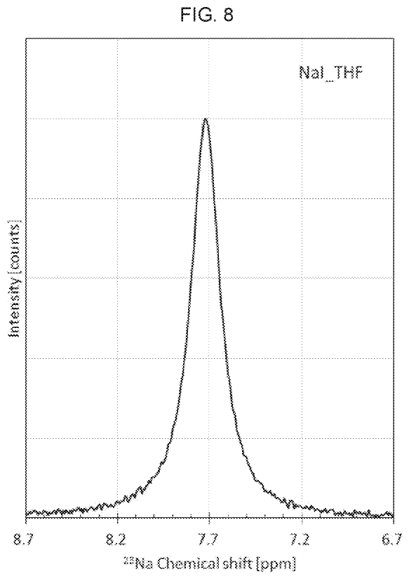

FIG. 8 shows the result of measuring the ²³Na-NMR spectrum when sodium iodide was dissolved at a concentration of 0.1 mol/L as a THF solution of the sodium source for the single-crystal spherical metal sodium nanoparticles. The peak of the chemical shift at 7.7 ppm is the peak obtained from the measurement of a solution of sodium chloride dissolved at 3 mol/L in heavy water as the chemical shift standard, in which the chemical shift was calibrated. FIG. 8 shows a state in which NaI was dissolved in THF and the sodium ions were solvated with THF, but strictly speaking, it shows a mixed solvation state of THF and water molecules derived from 10 ppm residual water remaining in the THF solvent. It has been confirmed that the chemical shift due to the residual water in the THF solvent becomes lower as the water concentration increases. The chemical shift at a residual water content of 50 ppm is estimated to be 7.5 ppm. The residual water more than this level causes oxidation of the single-crystal spherical metal sodium nanoparticles obtained by the production method of the present invention, and the deviation of the particle shape from sphere due to oxidation becomes significant. Therefore, it is preferable that the chemical shift of 23Na measured by ²³Na-NMR is 8.0 ppm or more and less than 7.5 ppm. The solvation state can also be confirmed from the spectral line width of ²³Na-NMR. The line width when a sodium ion is solvated with heavy water is 8.5 Hz, and the line width when solvated with THF and 10 ppm residual water is 21.3 Hz, confirming the increase in line width due to THE solvation.

Next, the prepared single-crystal spherical metal sodium nanoparticle reduction liquid (Liquid A) and the single-crystal spherical metal sodium nanoparticle raw material liquid (Liquid B) were mixed using a fluid processing apparatus described in Patent Literature 6 by the present applicant. Here, the fluid processing apparatus described in Patent Literature 6 is the apparatus described in FIG. 1 (A) of Patent Literature 6, in which the opening d2 of the second introduction part is a concentric annual shape surrounding the central opening of the processing surface 2, which is a disk formed in a ring shape. Specifically, the reduction liquid of Liquid A or the raw material liquid of Liquid B was introduced between the processing surfaces 1 and 2 from the first introduction part d1, and while the processing part 10 was rotated at a rotation speed of 500 rpm to 5,000 rpm, the other liquid in the raw material liquid of Liquid B and the reduction liquid of A, which is different from the liquid sent, was introduced between the processing surfaces 1 and 2 from the second introduction part d2, and the single-crystal spherical metal sodium nanoparticle raw material liquid and the single-crystal spherical metal sodium nanoparticle reduction liquid were mixed in the thin film fluid to precipitate the single-crystal spherical metal sodium nanoparticles between the processing surfaces 1 and 2. The discharged liquid containing the single-crystal spherical metal sodium nanoparticles was discharged from between the processing surfaces 1 and 2 of the fluid processing apparatus. The discharged single-crystal spherical metal sodium nanoparticle dispersion was collected in a beaker via a vessel. In order to block the liquid sent and the collected liquid from the atmosphere, the connecting pipe and the collection vessel were sealed pipes, and argon gas was flowed in this pipe for one hour to prevent the influence of the atmosphere.

Table 2 shows the operation conditions of the fluid processing apparatus of Example 1. The introduction temperatures (liquid sending temperatures) and introduction pressures (liquid sending pressures) of Liquid A and Liquid B shown in Table 2 were measured using a thermometer and a pressure gauge provided in the sealed introduction paths (first introduction part d1 and second introduction part d2) leading between the processing surfaces 1 and 2. The introduction temperature of Liquid A shown in Table 2 is the actual temperature of Liquid A under the introduction pressure in the first introduction part d1, and the introduction temperature of Liquid B is the actual temperature of Liquid B under the introduction pressure in the second introduction part d2.

TABLE 2

| | | Introduction flow | | Introduction | | Introduction | |
|---|---|---|---|---|---|---|---|
| | Disk | rate | | temperature | | pressure | |
| | rotation | (liquid sending flow | | (liquid sending | | (liquid sending | |
| | speed | rate) [mL/min] | | temperature) [° C.] | | pressure) [MPaG] | |
| | [rpm] | Liquid A | Liquid B | Liquid A | Liquid B | Liquid A | Liquid B |
| Example 1-1 | 5000 | 20 | 20 | 20 | 23 | <0.1 | <0.1 |
| Example 1-2 | 3500 | | | | | | |
| Example 1-3 | 2100 | | | | | | |
| Example 1-4 | 700 | | | | | | |

A wet cake sample was prepared from the single-crystal spherical metal sodium nanoparticle dispersion discharged from the fluid processing apparatus and collected in a beaker. The preparation method was performed according to a conventional method. The discharged single-crystal spherical metal sodium nanoparticle dispersion was collected, and the single-crystal spherical metal sodium nanoparticles were sedimented from the collected liquid by centrifugation (30,190 G for 2 hours), and the supernatant was removed. Then, ultrasonic cleaning with THF and sedimentation were repeated, and the nanoparticles in a wet cake state were collected in a sealed container and stored in a glove box under an argon atmosphere.

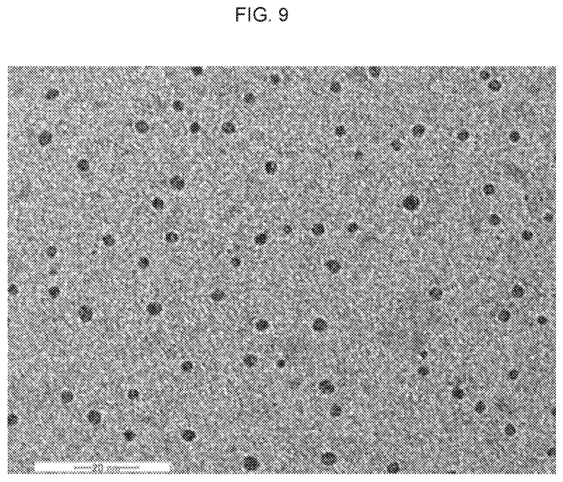

FIG. 9 shows a TEM image of the single-crystal spherical metal sodium nanoparticles of Example 1-1. It was confirmed that spherical metal sodium nanoparticles of less than 20 nm were produced. Similar results were confirmed for the single-crystal spherical metal sodium nanoparticles of Examples 1-2 to 1-4.

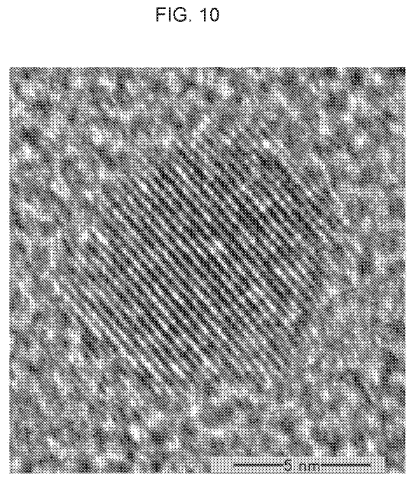

FIG. 10 shows a high-magnification TEM image of the single-crystal spherical metal sodium nanoparticles of Example 1-1. Similar results were confirmed for the single-crystal spherical metal sodium nanoparticles of Examples 1-2 to 1-4. Since lattice fringes were observed in one direction, it was confirmed that the nanoparticles were single crystals. The average lattice spacing measured from the seven interference fringes of the electron beam was 337 μm. This value is close to the lattice spacing of 353 μm for the 101 plane of metal sodium.

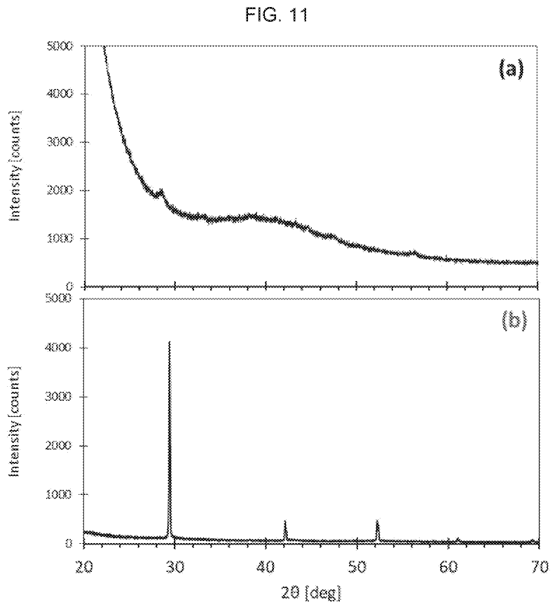

FIG. 11(a) shows an XRD pattern obtained by immersing the sediments obtained by centrifuging the single-crystal spherical metal sodium nanoparticles of Example 1-2 at 500 G for 30 minutes in mineral oil and measuring them by a reflection method. The crystallite diameter calculated by the Scherrer method from the half-width of the peak at a diffraction angle of 28.5° was 15.8 nm. The XRD pattern was obtained by measuring the metal sodium under a transmission method, which was collected as sediments under the conditions at 30,000 G for 2 hours, and was sandwiched between Mylar films in a glove box under an argon atmosphere. FIG. 11(b) shows the result of XRD measurement of the single-crystal spherical metal sodium nanoparticles of Example 1-2 in a state in which the precipitated particles were aggregated on a metal foil by a high acceleration of 30,000 G. The crystallite diameter calculated by the Scherrer method from the half-width of the peak at a diffraction angle of 29.4° in the XRD pattern was 456 nm.

It is known that the absorbance of metal nanoparticles varies depending on the refractive index of the solvent used in the absorbance measurement. In the case of metal silver, it is known that as the refractive index of the solvent increases, the absorption peak wavelength shifts to the longer wavelength side.

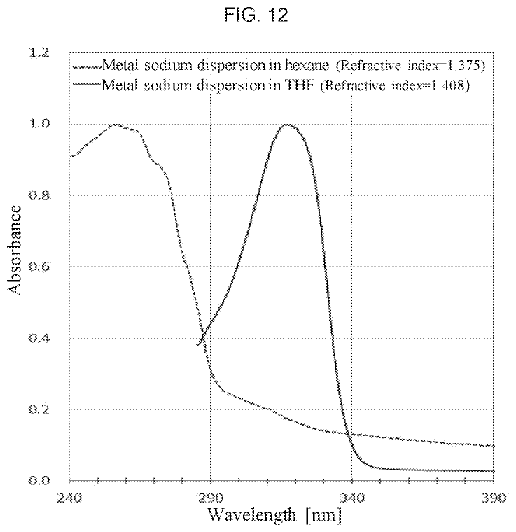

FIG. 12 shows ultraviolet-visible absorption spectra measured when the single-crystal spherical metal sodium nanoparticles obtained in Example 1-3 were dispersed in hexane or THF respectively. When the dispersion solvent was hexane, a maximum absorption was confirmed at 260 nm, and when the dispersion solvent was THF, a maximum absorption was confirmed at 315 nm. The refractive index of hexane was 1.375, and that of THF was 1.408. The results were obtained that the maximum wavelength of metal plasmon absorption shifts to the longer wavelength side as the refractive index of the dispersion solvent increases. All of these are thought to be absorption due to plasmon excitation of the single-crystal spherical metal sodium nanoparticles.

Non-Patent Literature 1 describes the relationship between the number of metal sodium atoms and the absorption of surface plasmons. According to this literature, when the number of metal sodium atoms is 300, the imaginary component of the dielectric constant that gives optical absorption is 4.6 eV (electron volts), which is considered to be the absorption maximum due to surface plasmons in clusters that are aggregates of metal sodium atoms. When this energy value is converted to a wavelength, it becomes 269.5 nm, which corresponds to the result in the case of hexane mentioned above, where the absorption maximum is confirmed at 260 nm. It is described that clusters with the number of sodium atoms of 150 to 200 atoms or more are approximately 2 nm or more, which corresponds to the diameter of the single-crystal spherical metal sodium nanoparticles produced by the present invention, which are about 5 nm.

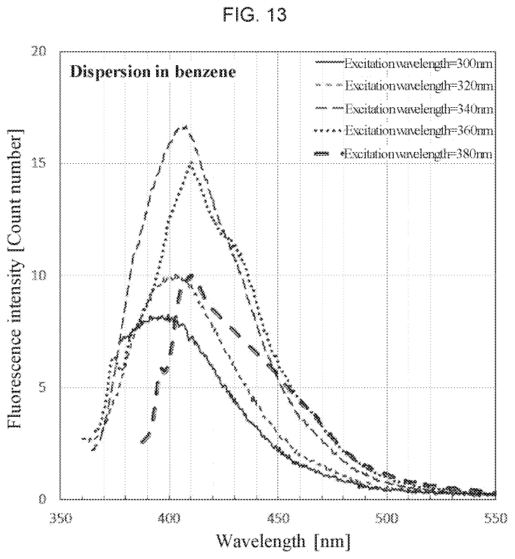

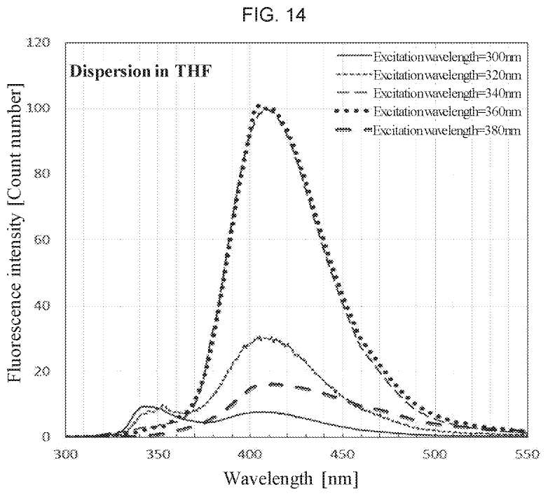

FIG. 13 and FIG. 14 show a fluorescence spectra of the single-crystal spherical metal sodium nanoparticles of Examples 1-4. The fluorescence spectra are ones normalized with the maximum intensity of the fluorescence spectrum obtained for each excitation wavelength set to 1.0, and are the results of changing the excitation wavelength from 320 nm to 380 nm in increments of 20 nm. From these results, it was confirmed that the fluorescence of the single-crystal spherical metal sodium nanoparticles of Examples 1-3 showed a maximum peak at 380 nm to 450 nm depending on the excitation wavelength. The results of Example 1 are shown in Table 3.

TABLE 3

| | | | | | UV-visible | |
|---|---|---|---|---|---|---|
| | Average | | | Average | absorption | Fluoresence |
| | particle | | | lattice | peak | peak |
| | diameter | Average | Space | spacing | wavelength | wavelength |
| | [nm] | circularity | lattice | [pm] | [nm] | [nm] |
| Example 1-1 | 12.5 | 0.94 | Cubic | 305 | 330 | 410 |
| Example 1-2 | 13.0 | 0.93 | Cubic | 305 | 334 | 412 |
| Example 1-3 | 13.2 | 0.93 | Cubic | 303 | 335 | 412 |
| Example 1-4 | 17.3 | 0.91 | Cubic | 303 | 335 | 416 |

### Comparative Example 1

The formulation of Comparative Example 1 was the same as that of Example 1 shown in Table 1, but the disk rotation speed was lowered to 600 rpm and 500 rpm to produce single-crystal spherical nanoparticles as shown in Table 4. Table 5 shows the results of the single-crystal spherical metal sodium nanoparticles obtained. By lowering the disk rotation speed to less than 700 rpm, no change was observed in the crystal structure, but the average circularity fell to less than 0.9.

TABLE 4

| | | Introduction flow | | Introduction | | Introduction | |
|---|---|---|---|---|---|---|---|
| | Disk | rate | | temperature | | pressure | |
| | rotation | (liquid sending flow | | (liquid sending | | (liquid sending | |
| | speed | rate) [mL/min] | | temperature) [° C.] | | pressure) [MPaG] | |
| | [rpm] | Liquid A | Liquid B | Liquid A | Liquid B | Liquid A | Liquid B |
| Comparative | 600 | 20 | 20 | 20 | 23 | <0.1 | <0.1 |
| Example 1-1 | | | | | | | |
| Comparative | 500 | | | | | | |
| Example 1-2 | | | | | | | |

TABLE 5

| | | | | | UV-visible | |
|---|---|---|---|---|---|---|
| | Average | | | Average | absorption | Fluoresence |
| | particle | | | lattice | peak | peak |
| | diameter | Average | Space | spacing | wavelength | wavelength |
| | [nm] | circularity | lattice | [pm] | [nm] | [nm] |
| Comparative | 20 | 0.87 | Cubic | 303 | 345 | 429 |
| Example 1-1 | | | | | | |
| Comparative | 25 | 0.85 | Cubic | 303 | 348 | 433 |
| Example 1-2 | | | | | | |

### Example 2

Example 2 shows the results of single-crystal spherical metal sodium nanoparticles produced when the single-crystal spherical metal sodium nanoparticle reduction liquid was set at 5° C. or 10° C. and the disk rotation speed was set at 5,000 rpm or 3,500 rpm. The compositions of the single-crystal spherical metal sodium nanoparticle reduction liquid and the single-crystal spherical metal sodium nanoparticle raw material liquid were the same as in Example 1, and the nanoparticles were produced under the conditions shown in Table 1. Table 6 shows the production conditions of Example 2, and the results of the obtained single-crystal spherical metal sodium nanoparticles are as shown in Table 7. For the single-crystal spherical metal sodium nanoparticles produced in Example 2, the lower the temperature of the single-crystal spherical metal sodium nanoparticle reduction liquid (Liquid A) was, the smaller the average particle diameter became.

TABLE 6

| | | Introduction flow | | Introduction | | Introduction | |
|---|---|---|---|---|---|---|---|
| | Disk | rate | | temperature | | pressure | |
| | rotation | (liquid sending flow | | (liquid sending | | (liquid sending | |
| | speed | rate) [mL/min] | | temperature) [° C.] | | pressure) [MPaG] | |
| | [rpm] | Liquid A | Liquid B | Liquid A | Liquid B | Liquid A | Liquid B |
| Example 2-1 | 5000 | 20 | 20 | 5 | 23 | 0.1 | 0.1 |
| Example 2-2 | 3500 | | | | | | |
| Example 2-3 | 5000 | | | 10 | | | |
| Example 2-4 | 3500 | | | | | | |

TABLE 7

| | | | | | UV-visible | |
|---|---|---|---|---|---|---|
| | Average | | | Average | absorption | Fluoresence |
| | particle | | | lattice | peak | peak |
| | diameter | Average | Space | spacing | wavelength | wavelength |
| | [nm] | circularity | lattice | [pm] | [nm] | [nm] |
| Example 2-1 | 12.7 | 0.94 | Cubic | 310 | 330 | 410 |
| Example 2-2 | 13.2 | 0.93 | Cubic | 309 | 333 | 410 |
| Example 2-3 | 11.6 | 0.95 | Cubic | 305 | 330 | 403 |
| Example 2-4 | 14.3 | 0.94 | Cubic | 304 | 335 | 410 |

### Comparative Example 2

The formulation of Comparative Example 2 was the same as that of Example 1 shown in Table 1, but as shown in Table 8, the disk rotation speed was reduced to 700 rpm, and the temperatures of the single-crystal spherical metal sodium nanoparticle reduction liquid of Liquid A were 5° C. or 10° C., and the single-crystal spherical metal sodium nanoparticles were produced. Table 9 shows the results of the produced single-crystal spherical metal sodium nanoparticles. The average circularity of the single-crystal spherical metal sodium nanoparticles produced by reducing the disk rotation speed to 700 rpm and keeping the temperature of Liquid A at 10° C. or below was less than 0.9.

TABLE 8

| | | Introduction flow | | Introduction | | Introduction | |
|---|---|---|---|---|---|---|---|
| | Disk | rate | | temperature | | pressure | |
| | rotation | (liquid sending flow | | (liquid sending | | (liquid sending | |
| | speed | rate) [mL/min] | | temperature) [° C.] | | pressure) [MPaG] | |
| | [rpm] | Liquid A | Liquid B | Liquid A | Liquid B | Liquid A | Liquid B |
| Comparative | 700 | 20 | 20 | 5 | 23 | <0.1 | <0.1 |
| Example 2-1 | | | | | | | |
| Comparative | 700 | | | 10 | | | |
| Example 2-2 | | | | | | | |

TABLE 9

| | | | | | UV-visible | |
|---|---|---|---|---|---|---|
| | Average | | | Average | absorption | Fluoresence |
| | particle | | | lattice | peak | peak |
| | diameter | Average | Space | spacing | wavelength | wavelength |
| | [nm] | circularity | lattice | [pm] | [nm] | [nm] |
| Comparative | 23.9 | 0.88 | Cubic | 308 | 342 | 423 |
| Example 2-1 | | | | | | |
| Comparative | 26.7 | 0.89 | Cubic | 305 | 349 | 428 |
| Example 2-2 | | | | | | |

### Example 3

In Example 3, the formulations of Liquid A and Liquid B were the same as those in Table 1, and single-crystal spherical metal sodium nanoparticles were produced by varying the flow rate ratio of the single-crystal spherical metal sodium nanoparticle raw material liquid (Liquid B) to the single-crystal spherical metal sodium nanoparticle reduction liquid (Liquid A). Table 10 shows the production conditions of the single-crystal spherical metal sodium nanoparticles. Table 11 shows the results of the obtained single-crystal spherical metal sodium nanoparticles.

TABLE 10

| | | Introduction flow | | Introduction | | Introduction | |
|---|---|---|---|---|---|---|---|
| | Disk | rate | | temperature | | pressure | |
| | rotation | (liquid sending flow | | (liquid sending | | (liquid sending | |
| | speed | rate) [mL/min] | | temperature) [° C.] | | pressure) [MPaG] | |
| | [rpm] | Liquid A | Liquid B | Liquid A | Liquid B | Liquid A | Liquid B |
| Example 3-1 | 5000 | 40 | 40 | 20 | 23 | <0.1 | <0.1 |
| Example 3-2 | | | 20 | | | | |
| Example 3-3 | | | 10 | | | | |

TABLE 11

| | | | | | UV-visible | |
|---|---|---|---|---|---|---|
| | Average | | | Average | absorption | Fluoresence |
| | particle | | | lattice | peak | peak |
| | diameter | Average | Space | spacing | wavelength | wavelength |
| | [nm] | circularity | lattice | [pm] | [nm] | [nm] |
| Example 3-1 | 12.6 | 0.94 | Cubic | 308 | 330 | 407 |
| Example 3-2 | 15.3 | 0.93 | Cubic | 308 | 330 | 408 |
| Example 3-3 | 15.7 | 0.93 | Cubic | 306 | 335 | 410 |

In Examples 1 to 3 of the present invention, the results are shown for the case where DBB was used as the aromatic compound in the single-crystal spherical metal sodium nanoparticle reduction liquid. However, the single-crystal spherical metal sodium nanoparticles could also be produced similarly when biphenyl, naphthalene, or phenanthrene was used in place of DBB.

### INDUSTRIAL APPLICABILITY

The single-crystal spherical metal sodium nanoparticles produced by the production method of the present invention can change their absorption peak by changing the refractive index of the dispersion solvent, and can emit fluorescence by forming nanoparticles with a particle diameter of about 10 nm. The single-crystal spherical metal sodium nanoparticles do not have the toxicity to living organisms, which compound semiconductors formed from cadmium, selenium, tellurium, etc. have, and therefore do not require their recovery after use and are environmentally safe. Furthermore, because the single-crystal spherical metal sodium nanoparticles are spherical, they can be densely packed with an electrode material for a solar battery, a secondary ion battery, etc., and can be used as a negative electrode of a lithium ion battery and an electrode material for a solar battery. They can also be widely used as a catalyst, a reducing agent, etc.

1. A method of producing single-crystal spherical metal sodium nanoparticles which are single crystals and spherical, comprising: a step of mixing and reacting a raw material liquid containing sodium halide and a reduction liquid containing an anion of an aromatic compound,
wherein the anion of the aromatic compound is prepared by mixing lithium, sodium or potassium with the aromatic compound.

2. The method according to claim 1, wherein an average value of circularities of the single-crystal spherical metal sodium nanoparticles is 0.85 or more,
wherein the circularity is defined by a circularity calculated by the formula: 4πS/Z², using the perimeter (Z) and area (S) of the projected image of the single-crystal spherical metal sodium nanoparticles.

3. The method according to claim 1, wherein the average particle diameter of the single-crystal spherical metal sodium nanoparticles is 1 nm to 300 nm.

4. The method according to claim 1, wherein the sodium halide is sodium iodide, and the molar ratio of lithium, sodium or potassium to sodium iodide is from 2:1 to 1:1.

5. The method according to claim 1, wherein the aromatic compound is at least one selected from the group consisting of 4,4′-di-tert-butylbiphenyl (DBB), biphenyl, naphthalene, and phenanthrene.

6. The method according to claim 1, wherein when the aromatic compound is DBB or biphenyl, the reduction liquid exhibits a lower chemical shift than the neutral aromatic compound in the ¹H-NMR spectrum.

7. The method according to claim 1, wherein when the aromatic compound is DBB or biphenyl, the reduction liquid exhibits a chemical shift value of 2 ppm or more in the ⁷Li-NMR spectrum.

8. The method according to claim 1, wherein the solvent contained in the reduction liquid is tetrahydrofuran, 2-methyltetrahydrofuran, 4-methyltetrahydropyran, 1,2-dimethoxyethane, or a mixture thereof, having a residual water content of 10 ppm or less and a residual oxygen concentration of less than 0.1 ppm.

9. The method according to claim 1, wherein the single-crystal spherical metal sodium nanoparticles are made of cubic crystals.

10. The method according to claim 1, wherein a dispersion obtained by dispersing the single-crystal spherical metal sodium nanoparticles in an organic solvent having an optical refractive index of 1.40 to 1.50 has an absorption peak at 270 nm to 340 nm in the ultraviolet-visible absorption spectrum.

11. The method according to claim 1, wherein the single-crystal spherical metal sodium nanoparticles have a fluorescence maximum in the wavelength range of 380 nm to 450 nm in the fluorescence spectrum.

12. The method according to claim 1, wherein the raw material liquid and the reduction liquid are mixed and reacted using an apparatus,
wherein the apparatus comprises a fluid pressure imparting mechanism for imparting a pressure to the reduction liquid; two processing members of a first processing member and a second processing member, the second processing member being capable of approaching to and separating from the first processing member; and a rotation drive mechanism for rotating the first processing member and the second processing member relative to each other; and
wherein each of the two processing members provides two processing surfaces of a first processing surface and a second processing surface disposed in a position facing with each other; each of the processing surfaces constitute part of a sealed flow path through which the reduction liquid under the pressure is passed;
the apparatus is for mixing and reacting the fluids to be processed, of the raw material liquid and the reduction liquid which contain reactants between both the processing surfaces;
of the first and second processing members, the second processing member is provided with a pressure-receiving surface, and a part of the pressure-receiving surface is comprised of the second processing surface;
the pressure-receiving surface receives pressure applied to the reduction liquid by the fluid pressure imparting mechanism and thereby generates a force to move in the direction of separating the second processing surface from the first processing surface;
the reduction liquid and the raw material liquid being the fluids to be processed under the predetermined pressure are passed between the first and second processing surfaces being capable of approaching to and separating from each other, at least one of which rotates relative to the other, whereby the fluids to be processed form a thin film fluid containing the single-crystal spherical metal sodium nanoparticles;
the apparatus further comprises an introduction path independent of the flow path through which the reduction liquid under the pressure is passed; and one opening leading to the introduction path and being arranged in the second processing surface; and
the raw material liquid is sent from the introduction path and introduced into between the first and second processing surfaces, and the reduction liquid and the raw material liquid are mixed in the thin film fluid.

13. The method according to claim 12, wherein the opening for introducing the sodium iodide raw material liquid is located downstream of a point at which the flow of the reduction liquid passing between the two processing surfaces becomes a laminar flow.
